(19) United States
(12) Patent Application Publication
(10) Pub. No.: US 2008/0068102 A1
(43) Pub. Date: Mar. 20, 2008

(54) Surface mount type crystal oscillator

(76) Inventors: Kouichi Moriya, Saitama (JP); Hidenori Harima, Saitama (JP)

Correspondence Address: Muirhead and Saturnelli, LLC, Suite 1001, 200 Friberg Parkway, Westborough, MA, 01581, US

(21) Appl. No.: 11/901,620

(22) Filed: Sep. 18, 2007

(30) Foreign Application Priority Data
Sep. 19, 2006 (JP) 2006-253133

(51) Int. Cl. H03B 1/00

(52) U.S. Cl. 331/68

(57) ABSTRACT

A surface mount type crystal oscillator includes a container main body including a recess on one main surface thereof and hermetically encapsulating an IC (integrated circuit) chip and a quartz crystal blank, and a mounting terminal electrically connected to the IC chip. The container main body includes a laminated ceramic made by laminating a flat layer and a frame wall layer, and a notch portion which is opened to the outer periphery of the container main body is formed on the flat layer within a region where the frame wall layer is laminated to the flat layer. A probe contact terminal electrically connected to the IC chip and/or the crystal blank is provided on the exposed surface of the frame wall layer by the notch portion. The mounting terminal is provided on the outer bottom face of the flat layer.

### BACKGROUND OF THE INVENTION

1. Field of the Invention

The present invention relates to a surface mount type crystal oscillator, and particularly to a surface mount type crystal oscillator having a probe contact terminal such as a crystal inspection terminal and a writing terminal.

2. Description of the Related Arts

Surface mount type quartz crystal oscillators formed by using a container for surface-mounting and integrating a crystal element with an IC (integrated circuit) chip having an oscillating circuit using the crystal element are widely used as reference sources of frequencies and time in mobile electronic apparatuses, particularly mobile phones, because of the reduced size and weight. One type of the surface mount type crystal oscillators comprises a probe contact terminal against which a probe is abutted from outside in inspection or the writing of data as shown in Japanese Patent Laid-Open No. 8-307153 (JP 8-307153A). Probe contact terminals include, for example, a crystal inspection terminal which is used for inspecting vibration characteristics of the crystal element and a writing terminal which is used when temperature compensation data is written in a temperature compensation mechanism in the IC chip. The probe contact terminal is provided on the outer surface of the bottom face or side face of a container main body of the crystal oscillator.

FIGS. 1A and 1B are, respectively, a sectional view and a bottom view showing an example of the configuration of a surface mount type crystal oscillator comprising a probe contact terminal as described above. The illustrated crystal oscillator uses container main body 1 having a recess, wherein IC chip 2 and crystal blank 3 are accommodated in the recess and the recess is closed by metal cover 4 to hermetically encapsulate IC chip 2 and crystal blank 3 in container main body 1. Container main body 1 comprises a laminated ceramic formed from substantially rectangular plate-like flat layer 5 and frame wall layer 6 having an opening in the central portion, and due to this configuration, container main body 1 has a flat and substantially rectangular parallelepiped outer shape which looks like a rectangle having short sides and long sides when viewed from above when mounted on a wiring board, and the recess described above is formed on one main surface thereof. A step portion is formed on the inner wall of the recess.

Flat layer 5 forms the bottom wall of the container main body, and is made by laminating at least first layer 5a and second layer 5b. At four corners of the outer bottom face of first layer 5a, that is, the outer bottom face of container main body 1, are provided mounting terminals 21 such as a power supply terminal, a ground terminal and an output terminal. Mounting terminals 21 are used for electrically and mechanically connecting the wiring board and the crystal oscillator when the crystal oscillator is surface-mounted on the wiring board.

This type of container main body 1 is generally produced by laminating a plurality of ceramic green sheets (i.e., unburned sheets of ceramic material) each having a size corresponding to the size of a plurality of container main bodies, burning or baking the laminate and then dividing the laminate into individual container main bodies 1. Thus, mounting terminal 21 is generally formed at some distance away from the outer periphery of the outer bottom face of container main body 1 at four corners for facilitating the division into individual container main bodies.

A plurality of through-holes 7 are provided on the central region of first layer 5a, and the laminated surface of second layer 5b with first layer 5a is exposed at the position of through-hole 7. The number of holes 7 provided is, for example, four, and probe contact terminal 8 is provided on the exposed surface of second layer 5b in each hole 7. In the example shown in JP 8-307153A, probe contact terminals 8 are writing terminals for writing temperature compensation data in the temperature compensation mechanism in IC chip 2. In another example, two of four probe contact terminals 8 are crystal inspection terminals 8a which are used for inspecting electrical characteristics of crystal blank 3, and the other two probe contact terminals 8 are writing terminals 8b. Probe contact terminal 8 is a terminal which is not used in a state of mounting the crystal oscillator on the wiring board and which should not be short-circuited with a circuit pattern on the wiring board. Therefore, when probe contact terminal 8 is provided on the bottom face of the container main body for surface-mounting, it is necessary to provide probe contact terminal 8 rearward with respect to mounting terminal 21 so that probe contact terminal 8 does not contact the wiring board.

IC chip 2 is substantially rectangular, and is made by integrating into a semiconductor substrate the oscillating circuit using crystal blank 3 and the temperature compensation mechanism compensating frequency temperature characteristics of crystal blank 3. Of opposite main surfaces of IC chip 2, a surface on which the oscillating circuit and the temperature compensation mechanism are formed in the semiconductor substrate is referred to as a circuit forming surface. On the circuit forming surface are also formed a plurality of terminals for connecting IC chip 2 to an external circuit. These terminals include a power supply terminal, a ground terminal, an oscillation output terminal, a pair of terminals for connection to the crystal blank, an AFC terminal to which an automatic frequency control (AFC) signal is supplied, an input terminal for writing data in the temperature compensation mechanism, and so on.

On the inner bottom surface of the recess of container main body 1 is formed a circuit pattern (not shown) comprised of a circuit terminal corresponding to the terminal on the IC chip 2 side and a conductive path. IC chip 2 is fixed on the inner bottom surface of the recess with the circuit forming surface facing the inner bottom surface of the recess by bonding the terminal of IC chip 2 and the circuit terminal on the inner bottom face of the recess by flip chip bonding by ultrasonic thermo-compression bonding using, for example, a bump. As a result, IC chip 2 is electrically connected to mounting terminal 21 through the laminated surface of ceramic sheets in container main body 1 and a through-hole plated portion (not shown) formed on the side surface of container main body 1. The temperature compensation mechanism in IC chip 2 is connected to writing terminal 8b as probe contact terminal 8.

As shown in FIG. 2, crystal blank 3 is, for example, an AT-cut quartz crystal blank having a rectangular shape. Excitation electrodes 9 are provided on the opposite main surfaces of crystal blank 3, respectively, and extending electrodes 10 are extended from excitation electrodes 9 toward opposite sides of one end of crystal blank 3, respectively. Opposite sides of one end at which extending electrodes 10 are extended are fixed on the top surface of the step portion in the recess of container main body 1 by conductive adhesive 11, whereby crystal blank 3 is held horizontally in the recess (as shown in FIG. 1A). Crystal blank 3 is electrically connected to IC chip 2 and crystal inspection terminal 8a through a conductive path (not shown).

Metal cover 4 is, for example, a plate-like member formed by kovar which is plated with nickel. On the upper surface of container main body 1, metal ring 20 is provided along the peripheral edge of the opening of the recess, and metal cover 4 is bonded to metal ring 20 by seam welding. Seam welding is carried out by abutting a pair of metal rollers (not shown) against opposite sides of metal cover 4, moving metal roller 4 along the sides of metal cover 4 while rotating metal roller 4, and passing a current between a pair of metal rollers. Plated nickel is melted by Joule heat from the current to bond metal cover 4 to metal ring 20.

Manufacturing processes for such a crystal oscillator will now be described.

First, IC chip 2 and crystal blank 3 are accommodated in container main body 1, and metal cover 4 is bonded, followed by inspecting vibration characteristics of crystal blank 3 as a crystal element using crystal inspection terminal 8a and removing defective products. In this connection, since after the fixation and sealing of crystal blank 3, the environment is changed to cause a change in vibration characteristics, particularly the crystal impedance (CI) that is one of oscillation conditions is measured in the inspection. Temperature compensation data is then written in the temperature compensation mechanism in IC chip 2 from writing terminal 8b. Temperature compensation data is based on the result of pre-measuring a change in oscillation frequency with temperature. By writing temperature compensation data, the frequency deviation Δf/f with temperature can be kept within specifications, for example within ±1 ppm provided that the nominal oscillation frequency of the crystal oscillator is f and the change amount of actual oscillation frequency from f is Δf.

Although not described in JP 8-307153A, the crystal oscillator is normally mounted in a measurement tool provided with a probe having an elastic mechanism so that a probe is abutted against probe contact terminal 8 in the inspection of vibration characteristics and the writing of temperature compensation data. Then, the inspection of vibration characteristics and the writing of temperature compensation data are performed using a measurement apparatus connected to the measurement tool.

However, the surface mount type crystal oscillator having the configuration described above has been progressively miniaturized to have outside planar dimensions of, for example, 3.2 mm×2.5 mm or smaller. As a result, the diameter of through-hole 7 of first layer 5a, in which probe contact terminal 8 is provided, also decreases. Thus, it has become difficult to insert into through-hole 7 the probe provided in the measurement tool to abut the probe against probe contact terminal 8.

It is also possible to provide probe contact terminals on a pair of opposite outer side faces of container main body 1 using a technique such as through-hole plating. In this case, however, the measurement tool requires an elastic mechanism in which probe 13 moves along a curved track in a three-dimensional space as schematically shown in FIG. 3. In contrast to this, in the example described above, probe contact terminals 8 are provided on the bottom face of the container main body, i.e. in the same plane, and therefore an elastic mechanism can be used in which the probe moves along a linear track in the same direction. Thus, provision of the probe contact terminals on the bottom face rather than the outer side face of the container main body can make the elastic mechanism in the measurement tool more simpler and more reliably abut the probe against the probe contact terminals.

As a technique related to the present invention, the assignee of the present invention has already disclosed in Japanese Patent Laid-Open Application No. 2002-76775 (JP 2002-076775A) that for placing chip parts such as a high-capacity capacitor and a thermistor which are associated with the oscillating circuit but difficult to be included in the integrated circuit, a notch portion is provided on a bottom wall layer having mounting terminals formed thereon in the surface mount type crystal oscillator, and these chip parts are placed in the notch portion. The notch portion is formed so as to be opened to sides surrounding the bottom face at a position corresponding to the outer periphery of the bottom face of the crystal oscillator. In this case, the depth of the notch portion should be greater than the height of the chip part because the chip part is placed in the notch portion. Since the height of the chip part is typically 600 μm and the height of the IC chip is 150 μm, the height of the crystal oscillator is so great that the miniaturization of the crystal oscillator is hindered in the configuration in which the chip part is placed in the notch portion. Furthermore, the assignee of the present invention has disclosed in US 2007/0120614A that in a crystal oscillator which uses a flat ceramic substrate rather than using a container main body having a recess and has an IC chip fixed on the surface of the ceramic substrate, a notch portion is formed in the bottom face of the ceramic substrate such that the outer periphery of the notch portion is opened to at least one of sides surrounding the bottom face of the ceramic substrate. A crystal inspection terminal or a writing terminal is provided in the notch portion.

### SUMMARY OF THE INVENTION

It is an object of the present invention to provide a surface mount type crystal oscillator which uses a container main body having a recess and is provided with a mounting terminal and a probe contact terminal on the bottom face, wherein a probe can easily be abutted against the probe contact terminal despite the progressive miniaturization.

According to the first aspect of the present invention, there is provided a surface mount type crystal oscillator comprising: a crystal blank; an IC chip including at least an oscillating circuit using the crystal blank; a container main body provided with a recess on one main surface thereof, the IC chip and the crystal blank in the recess hermetically encapsulating in the recess; and a probe contact terminal formed on an outer surface of the container main body and electrically connected to the IC chip and/or the crystal blank, wherein the container main body comprises a laminated ceramic in which a flat layer and a frame wall layer which forms a side wall of the recess are laminated, a mounting terminal electrically connected to the IC chip is provided on an outer bottom face of the flat layer, a notch portion which is opened to outer periphery of the container main body is formed on the flat layer within a region where the frame wall layer is laminated on the flat layer, and an upper layer just above the flat layer is exposed at the notch portion, and the probe contact terminal is provided on an exposed surface of the upper layer by the notch portion.

According to the second aspect of the present invention, there is provided a surface mount type crystal oscillator comprising: a crystal blank; an IC chip including at least an oscillating circuit using the crystal blank; a container main body provided with a first recess and a second recess on opposite main surfaces, respectively, the crystal blank hermetically encapsulated in the first recess and the IC chip accommodated in the second recess; a probe contact terminal formed on the outer surface of the container main body and electrically connected to the IC chip and/or the crystal blank; and a mounting terminal electrically connected to the IC chip, wherein the container main body comprises a laminated ceramic including a flat layer, an upper frame wall layer laminated on a first main surface of the flat layer and forming a side wall of the first recess, and a lower frame wall layer laminated on a second main surface of the flat layer and forming a side wall of the second recess, the mounting terminal is provided on an outer bottom face of the lower frame wall layer, a notch portion which is opened to outer periphery of the container main body is formed on the lower frame wall layer, and an upper layer just above the lower frame wall layer is exposed at the notch portion, and the probe contact terminal is provided on an exposed surface of the upper layer by the notch portion.

According to the third aspect of the present invention, there is provided a surface mount type crystal oscillator comprising: a crystal unit having a crystal blank hermetically encapsulated in a container main body; an IC chip including at least an oscillating circuit using the crystal unit; a mounting substrate including a recess on one main surface thereof, with the IC chip accommodated in the recess; and a probe contact terminal formed on an outer surface of the mounting substrate and electrically connected to the IC chip and/or the crystal blank, wherein the mounting substrate comprises a laminated ceramic in which a flat layer and a frame wall layer is laminated, the flame wall layer forming a side wall of the recess and being bonded to the crystal unit, a mounting terminal electrically connected to the IC chip is provided on an outer bottom face of the flat layer, a notch portion which is opened to outer periphery of the mounting substrate is formed on the flat layer within a region where the frame wall layer is laminated on the flat layer, and an upper layer just above the flat layer is exposed at the notch portion, and the probe contact terminal is provided on an exposed surface of the upper layer by the notch portion.

According to the fourth aspect of the present invention, there is provided a surface mount type crystal oscillator comprising: a crystal unit having a crystal blank hermetically encapsulated in a container main body; an IC chip including at least an oscillating circuit using the crystal unit; a mounting substrate including a recess on one main surface thereof, with the IC chip accommodated in the recess; and a probe contact terminal formed on an outer surface of the mounting substrate and electrically connected to the IC chip and/or the crystal blank, wherein the mounting substrate comprises a laminated ceramic made by laminating a flat layer bonded to the crystal unit and a frame wall layer forming a side wall of the recess, a mounting terminal electrically connected to the IC chip is provided on an outer bottom face of the frame wall layer, a notch portion which is opened to outer periphery of the mounting substrate is formed on the frame wall layer, and an upper layer just above the frame wall layer is exposed at the notch portion, and the probe contact terminal is provided on an exposed surface of the upper layer by the notch portion.

### BRIEF DESCRIPTION OF THE DRAWINGS

FIGS. 1A and 1B are, respectively, a sectional view and a bottom view showing an example of the configuration of a conventional surface mount type crystal oscillator;

FIG. 2 is a plan view showing a crystal blank;

FIG. 3 is a schematic side view showing an example of movement of a probe to a probe contact terminal;

FIGS. 4A and 4B are, respectively, a sectional view and a bottom view showing an example of the configuration of a surface mount type crystal oscillator according to a first exemplary embodiment;

FIG. 4C is a sectional view showing another example of the surface mount type crystal oscillator according to the first exemplary embodiment;

FIG. 5A is a sectional view showing an example of the surface mount type crystal oscillator according to a second exemplary embodiment;

FIG. 5B is a sectional view showing another example of the surface mount type crystal oscillator according to the second exemplary embodiment;

FIGS. 6A and 6B are, respectively, a sectional view and a bottom view showing an example of the configuration of the surface mount type crystal oscillator according to a third exemplary embodiment;

FIG. 7 is a sectional view showing an example of the surface mount type crystal oscillator according to a fourth exemplary embodiment;

FIG. 8A is a sectional view showing an example of the surface mount type crystal oscillator according to a fifth exemplary embodiment;

FIG. 8B is a sectional view showing another example of the surface mount type crystal oscillator according to the fifth exemplary embodiment;

FIG. 9A is a sectional view showing an example of the surface mount type crystal oscillator according to a sixth exemplary embodiment; and

FIG. 9B is a sectional view showing another example of the surface mount type crystal oscillator according to the sixth exemplary embodiment.

### DETAILED DESCRIPTION OF THE PREFERRED EMBODIMENTS

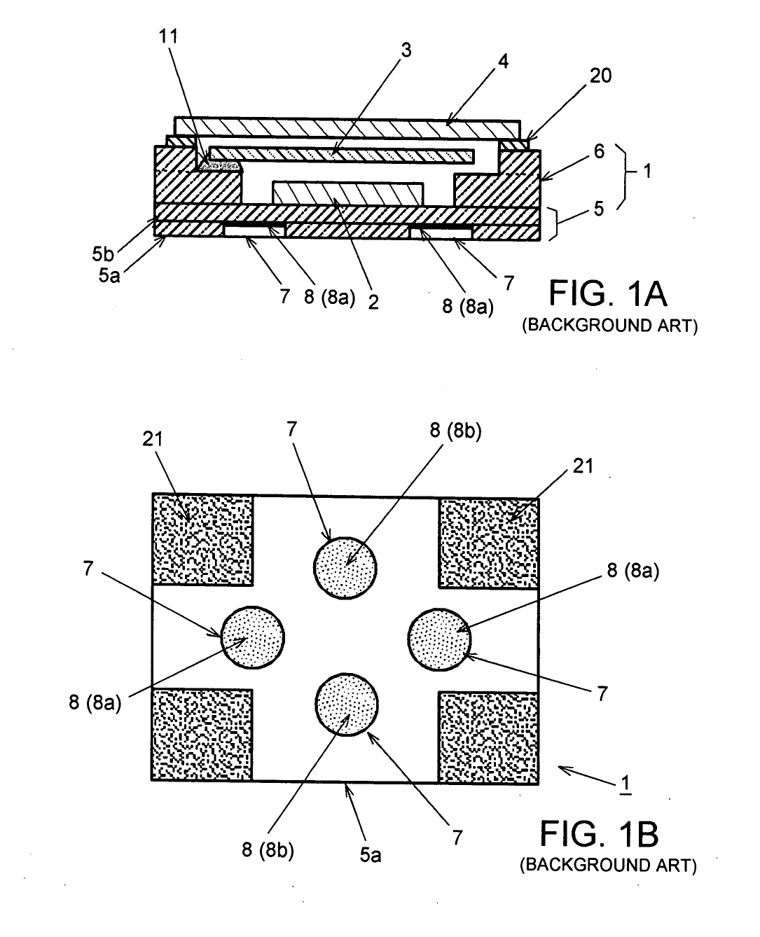

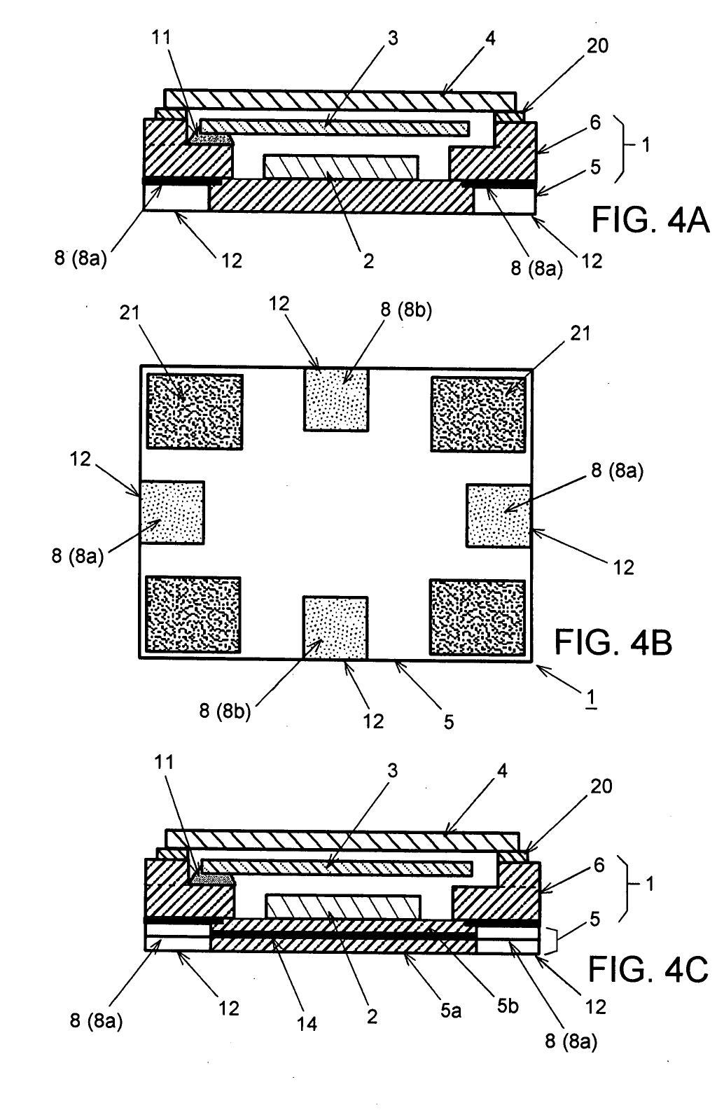

In FIGS. 4A and 4B showing a surface mount type crystal oscillator according to a first exemplary embodiment, same reference symbols will be given to same components as in FIGS. 1A and 1 B to avoid redundant explanations.

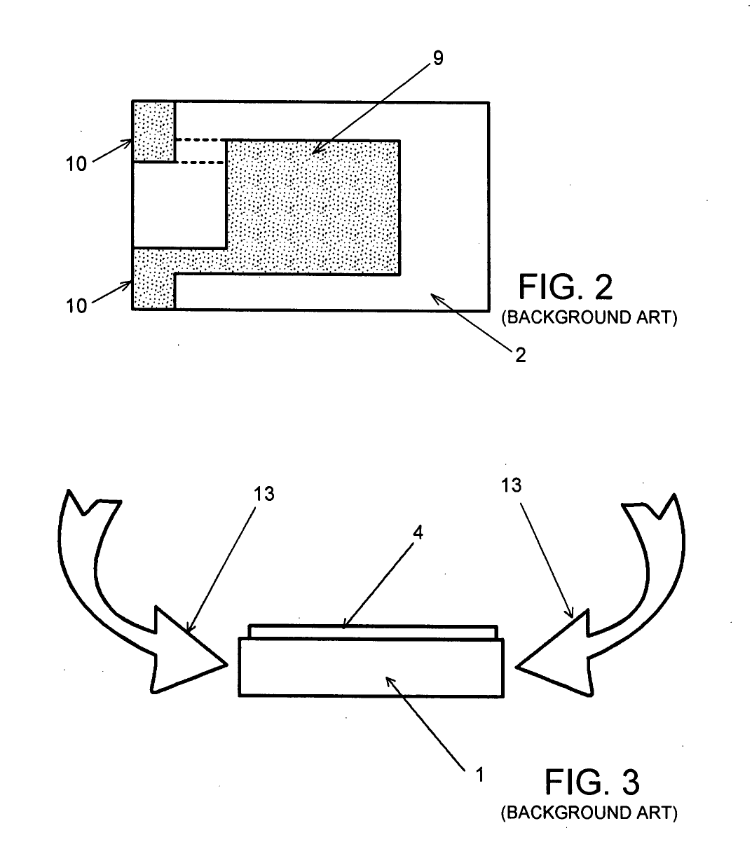

In the surface mount type crystal oscillator of the first exemplary embodiment, container main body 1 is used which has a shape of substantially rectangular parallelepiped and is provided with a recess formed on one main surface, as with the crystal oscillator described previously. IC chip 2 and quartz crystal blank 3 are accommodated in the recess, and metal cover 4 is bonded to container main body 1 by seam welding to hermetically encapsulate IC chip 2 and crystal blank 3 in container main body 1. IC chip 2 is fixed on the inner bottom surface of the recess. Crystal blank 3 is an AT-cut quartz crystal blank similar to that shown in FIG. 2, and opposite sides of one end of crystal blank 3 are fixed on the top surface of a step portion formed on the inner side surface of the recess. The container main body has outer planner dimensions of, for example, 3.2 mm×2.5 mm. Container main body 1 is formed by a laminated ceramic comprising substantially rectangular flat layer 5 forming the bottom wall of the recess and frame-shaped frame wall layer 6 laminated on one surface of flat layer 5 and having an opening. Here, as an example, flat layer 5 comprises a single-layer ceramic sheet. The recess of container main body 1 is defined by the substantially rectangular opening formed on frame wall layer 6. Here, the frame width in frame wall layer 6, that is, the interval between the inner side surface of the recess and the outer side surface of container main body 1, is, for example, 0.35 mm. In this exemplary embodiment, flat layer 5 functions as a lower layer, and frame wall layer 6 functions as an upper layer for flat layer 5.

As in the case described above, at four corners of the outer bottom face of container main body 1 are provided mounting terminals 21, respectively. In the crystal oscillator of this exemplary embodiment, notch portion 12 is provided on flat layer 4 forming the outer bottom face of container main body 1 at a position of a central region of each side surrounding the outer bottom face, that is, a position between a pair of mounting terminals sharing the adjacent side. Each notch portion 12 is within a small rectangular region which is placed so as to contact a side of the outer bottom face of container main body 1 and is provided with no flat layer 5, with frame wall layer 6 laminated on flat layer 5 at the position in which the region is formed. Therefore, the laminated surface of frame wall layer 6 on flat layer 5 is exposed at the position of notch portion 12. Notch portion 12 is surrounded in three directions by flat layer 5 and opened in the other one direction to the side of the outer periphery of container main body 1.

Probe contact terminal 8 is formed on the exposed surface of frame wall layer 6 in each notch portion 12. The size of the exposed surface is, for example, 300 μm in the direction of the frame width of frame wall layer 6, and 600 μm in the direction along the side of the outer bottom face of container main body 1. Here, a metal film larger than notch portion 12 is formed on the lower surface of frame wall layer 6, and flat layer 5 covers the outer periphery portion of the metal film to thereby form probe contact terminal 8 on the entire exposed surface of frame wall layer 6.

Such container main body 1 is fabricated by laminating a ceramic green sheet for a flat layer having a size corresponding to the size of a plurality of container main bodies and a ceramic green sheet for a frame wall layer having the same size, burning or baking the laminate and then dividing the laminate into individual container main bodies. At this time, notch portion 12 and the metal film for probe contact terminal 8 are formed at the stage of the ceramic green sheet before burning. In this way, through-holes are provided in the ceramic green sheet before being laminated and burned, and the laminate is divided into individual container main bodies 1 after lamination and burning, and therefore the fabrication process is facilitated as compared to a case where the probe contact electrode is provided on the outer side face of container main body 1 by through-hole processing.

In this exemplary embodiment, two of four probe contact terminals 8 provided are writing terminals 8b for temperature compensation data electrically connected to a temperature compensation mechanism of IC chip 2, and the other two probe contact terminals 8 are crystal inspection terminals 8a connected to crystal blank 3. For example, probe contact terminals 8 provided on a pair of long sides of the outer bottom face of container main body 1 are writing terminals 8b, and probe contact terminals 8 provided on short sides are crystal inspection terminals 8a.

In this configuration, notch portion 12 formed on flat layer 5 is opened to the outer periphery of the outer bottom face of container main body 1, and therefore movement of the probe is not limited at the opened end side of notch portion 12 as compared to a conventional crystal oscillator in which the probe contact terminal is provided on the bottom face of a hole entirely surrounded by the flat layer. As a result, in the crystal oscillator of this exemplary embodiment, the probe can easily be abutted against probe contact terminal 8 in the measurement tool. Furthermore, since probe contact terminal 8 is formed on the entire exposed surface of frame wall layer 6 which is the bottom face of notch portion 12, the probe can be prevented from being abutted against a region provided with no probe contact terminal. Probe contact electrode 8 extends to the end of the outer bottom face of container main body 1 on the outer periphery side in notch portion 12, and therefore even if the tip of a needle-like conical probe is somewhat shifted outward from the position of notch portion 12, the probe is abutted at the conical face against the outer periphery end, that is, the edge portion of the probe contact electrode, thus ensuring electrical connection between the probe and the probe contact electrode. In this exemplary embodiments, a measurement tool having an elastic mechanism of simple configuration in which the probe moves along a linear track in the same direction can be used, since probe contact terminal 8 is provided on the bottom face of the container main body.

In this crystal oscillator, the strength of container main body 1 is maintained even though notch portion 12 is provided, since notch portion 12 is formed only within a region where frame wall layer 6 is formed. The thickness of flat layer 5 can be about 300 μm like a flat layer that is used in a usual crystal oscillator, and therefore the height dimension of the crystal oscillator can be kept small, e.g., at 1.0 mm or less.

Another example of the configuration of the crystal oscillator according to the first exemplary embodiment will now be described. In the example shown in FIGS. 4A and 4B, flat layer 5 comprises a single-layer ceramic sheet, but flat layer 5 made by laminating a plurality of ceramic sheets may be used. The surface mount type crystal oscillator shown in FIG. 4C uses flat layer 5 having a configuration in which first layer 5a and second layer 5b are laminated. At four corners of the outer bottom face of first layer 5a are provided mounting terminals 21, respectively, and the surface of second layer 5b is the inner bottom surface of the recess of container main body 1, and IC chip 2 is fixed thereon. Shield electrode 14 is formed on the laminated surface of first layer 5a and second layer 5b. Shield electrode 14 is electrically connected to metal cover 4 and mounting terminal 21 for ground. By providing shield electrode 14 in this way, container main body 1 functions as a shield case in which electric fields from its opposite main surfaces are shielded. In this case, flat layer 5 comprising first layer 5a and second layer 5b is provided with notch portion 12 as in the case described above, the lower surface of frame wall layer 6 is exposed at notch portion 12, and probe contact electrode 8 is formed on the exposed surface.

The surface mount type crystal oscillator according to a second exemplary embodiment will now be described. In this and subsequent exemplary embodiments, same reference symbols will be given to same components as in the first exemplary embodiment, and redundant explanations of these components will not be described.

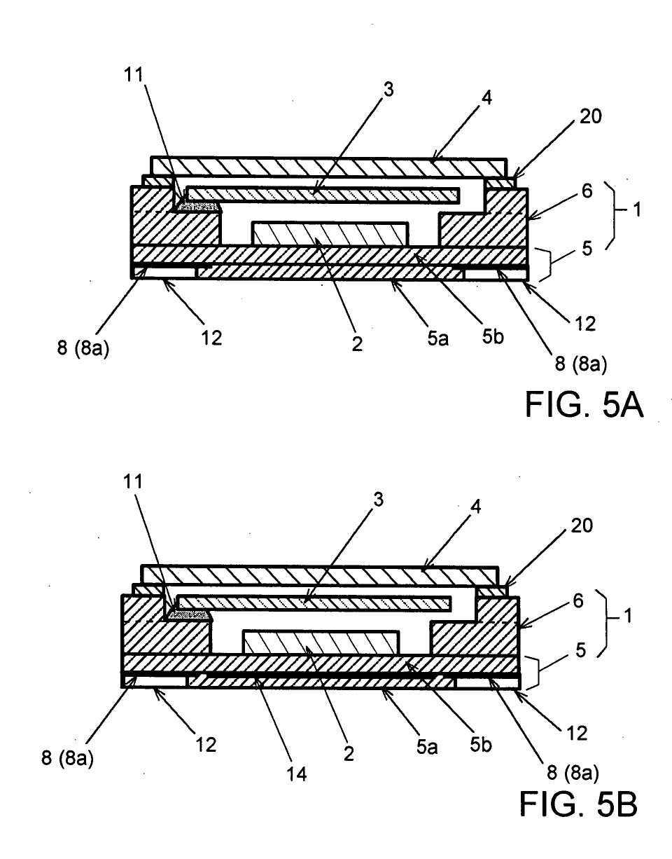

The crystal oscillator of the second exemplary embodiment shown in FIG. 5A is similar to that of the first exemplary embodiment, but is different from that of the first exemplary embodiment in the configuration of flat layer 5. In the crystal oscillator shown in FIG. 5A, flat layer 5 of container main body 1 is made by laminating first layer 5a and second layer 5b, mounting terminal 21 is provided at each of four corners of the outer bottom face of first layer 5a, and IC chip 2 is fixed on the surface of second layer 5b. Frame wall layer 6 is laminated on second layer 5b. First layer 5a has a thickness smaller than that of second layer 5b. Second layer 5b functions as an upper layer for first layer 5a as a lower layer.

In this crystal oscillator, notch portion 12 for providing probe contact terminal 8 is formed only on first layer 5a. Namely, notch portion 12 is provided on first layer 5a at the position of the central region of each side surrounding the outer bottom face of container main body 1. Each notch portion 12 is within a small rectangular region which is placed so as to contact a side of the outer bottom-face of container main body 1 and is provided with no first layer 5a, with frame wall layer 6 laminated on second layer 5b at the position in which the region is formed. The laminated surface of second layer 5b on first layer 5a is exposed at the position of notch portion 12. Notch portion 12 is surrounded in three directions by first layer 5a and opened in the other one direction to the side of the outer periphery of container main body 1.

Probe contact terminal 8 is formed on the exposed surface of second layer 5b at notch portion 12 as in the case described above. Of four probe contact terminals thus provided, for example, probe contact terminals 8 provided on a pair long sides of the outer bottom face of container main body 1 are writing terminals 8b, and probe contact terminals 8 provided on short sides are crystal inspection terminals 8a.

In this configuration, notch portion 12 formed on first layer 5a is opened to the outer periphery of the outer bottom face of container main body 1, and therefore the probe can easily be abutted against probe contact terminal 8 formed on the bottom face of notch portion 12. Furthermore, since probe contact terminal 8 is provided on the bottom face of the container main body, a measurement tool having an elastic mechanism of simple configuration in which the probe moves along a linear track in the same direction can be used.

In this exemplary embodiment, a layer made by laminating first layer 5a and second layer 5b is used as flat layer 5 for use as a bottom wall layer of container main body 1, and notch portion 12 is provided only on first layer 5a. Therefore, the depth of notch portion 12 can be reduced as compared to a case where notch portion 12 extending across the entire thickness of flat layer 5 as in the first exemplary embodiment. The smaller the thickness of first layer 5a, the smaller the difference in height between the exposed surface of second layer 5b, i.e. probe contact terminal 8, and the surface of first layer 5a and the smaller the depth of insertion of the probe when abutting the probe against probe contact terminal 8, thus making it possible to abut the probe more easily.

In this example, notch portion 12 is formed only within a range where frame wall layer 6 is laminated on second layer 5b, thus making it possible to prevent a reduction in strength resulting from provision of notch portion 12. In contrast to this, if a hole is provided within a region provided with a recess for accommodating IC chip 2 and crystal blank 3 in container main body 1 as in JP 8-307153A, stresses produced when a metal cover is seam-welded and stresses due to a difference in coefficient of thermal expansion between the wiring board and the crystal oscillator when the latter is mounted on the former may be concentrated on second layer 5b in a region where a hole is formed, resulting in possible emergence of cracks.

In the crystal oscillator of the second exemplary embodiment, shield electrode 14 can be provided on the laminated surface of first layer 5a and second layer 5b to form container main body 1 as a shield case in which electric fields from its opposite main surfaces are shielded, as shown in FIG. 5B. In this case, shield electrode 14 is electrically connected to metal cover 4 and mounting terminal 21 for ground.

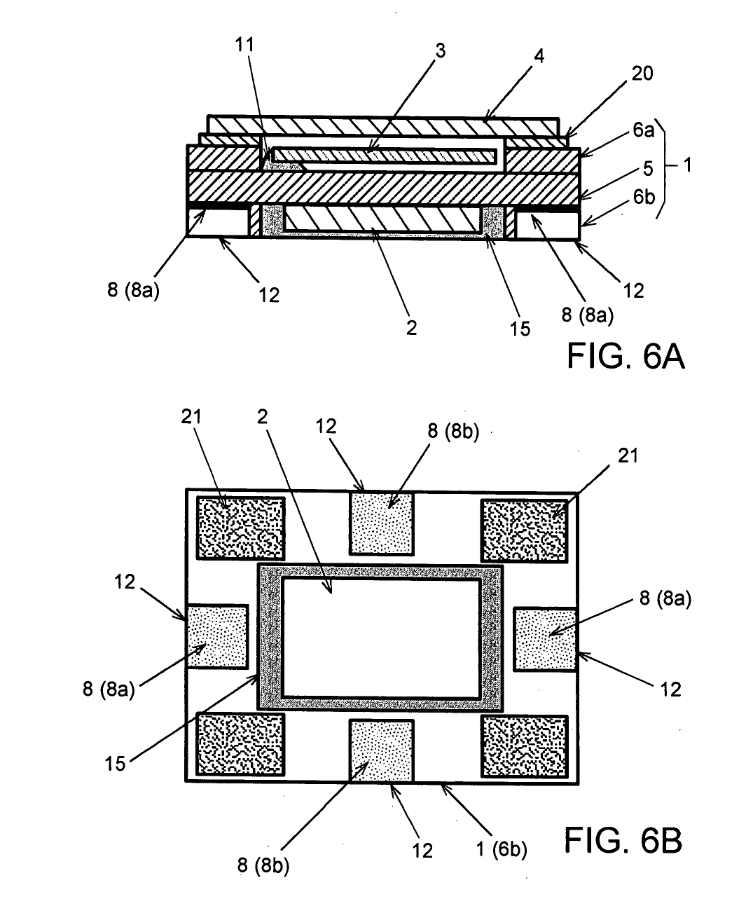

The surface mount type crystal oscillator according to a third exemplary embodiment shown in FIGS. 6A and 6B is made by using container main body 1 having recesses on opposite main surfaces, respectively, accommodating crystal blank 3 in one recess and hermetically encapsulating crystal blank 3 in the one recess by metal cover 4, and accommodating IC chip 2 in the other recess. Crystal blank 3 is an AT-cut quartz crystal blank similar to that shown in FIG. 2.

Container main body 1 is formed by a laminated ceramic comprising a substantially rectangular flat layer 5, frame-shaped upper frame wall layer 6a laminated on one main surface of flat layer 5 and having an opening, and frame-shaped lower frame wall layer 6b laminated on the other main surface of flat layer 6 and having an opening. Recesses are formed on upper and lower main surfaces, respectively, and thereby container main body 1 has an H-shaped section.

In the first recess defined by flat layer 5 and upper frame wall layer 6a, opposite sides of one end of crystal blank 3 are fixed on the inner bottom surface of the recess by conductive adhesive 11, whereby crystal blank 3 is held horizontally in the first recess. Metal ring 20 is provided on the peripheral edge of the opening of the first recess, metal cover 4 is bonded to metal ring 20 by seam welding, and crystal blank 3 is hermetically encapsulated in the first recess.

In the second recess defined by flat layer 5 and lower frame wall layer 6b, IC chip 2 is fixed on its bottom surface by flip chip bonding using a bump. Resin 15 protecting IC chip 2 is filled in the second recess. Although not shown here, a via-hole for electrically connecting IC chip 2 and crystal blank 3 is formed on flat layer 5.

At four corners of the outer bottom face of container main body 1, that is, four corners of the surface of lower frame wall layer 6b, mounting terminals 21 electrically connected to IC chip 2 are provided. Mounting terminals 21 include a power supply terminal, an earth terminal, an output terminal and so on.

In this exemplary embodiment, notch portion 12 is provided on the central region of each side of lower frame wall layer 6b, that is, at the position between mounting terminals 21. Each notch portion 12 is a small rectangular region which is provided on the outer periphery of lower frame wall layer 6b so as to contact the side of the outer bottom face of container main body 1, and the 25 region is only a region where lower frame wall layer 5b is not formed.

Therefore, notch portion 12 is surrounded in three directions by lower frame wall layer 6b and opened in the other direction to the side of the outer periphery of container main body 1. In notch portion 12, the lower surface of flat layer 5 is exposed, and probe contact terminal 8 is formed on the exposed surface. Of four probe contact terminals thus provided, for example, probe contact terminals 8 provided on a pair of long sides of lower frame wall layer 6b are writing terminals 8b electrically connected to a temperature compensation mechanism in IC chip 2, and probe contact terminals 8 provided on short sides are crystal inspection terminals 8a electrically connected to crystal blank 3.

In this configuration, notch portion 12 formed on lower frame wall layer 6b is opened to the outer periphery of the outer bottom face of container main body 1, and therefore the probe can easily be abutted against probe contact terminal 8 formed on the bottom face of notch portion 12 when a measurement tool is used. Furthermore, the resin does not flow into notch portion 12 when filling resin 15 in the second recess, since notch portion 12 does not communicate with the second recess. Therefore, resin 15 does not cover the probe contact terminal, and thus electrical connection of the probe to the probe contact terminal can be ensured.

In this exemplary embodiment, only probe contact terminal 8 is provided on notch portion 12, and therefore the depth of notch portion 12 can be comparable to the height of IC chip 12, for example about 150 μm, thus making it possible to keep the height dimension of the crystal oscillator small.

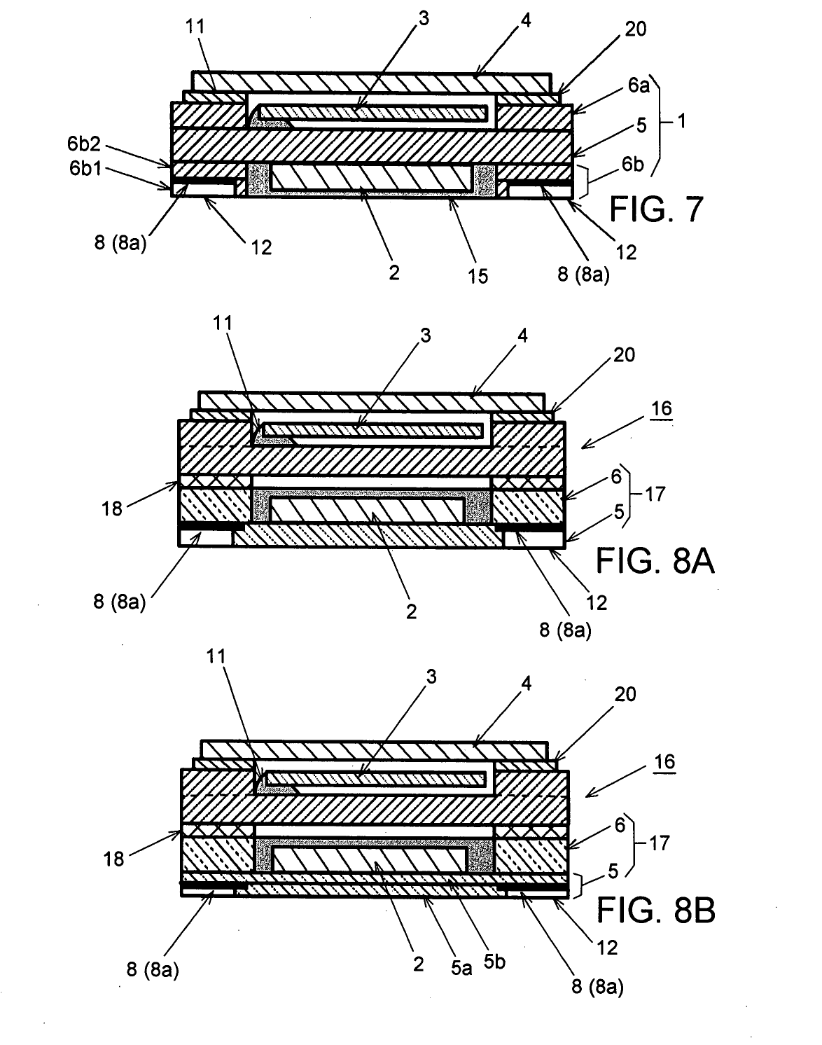

The surface mount type crystal oscillator according to a fourth exemplary embodiment shown in FIG. 7 is similar to that of the third exemplary embodiment, but is different from that of the third exemplary embodiment in the configuration of lower frame wall layer 6b. In the crystal oscillator shown in FIG. 7, lower frame wall layer 6b is made by laminating first layer 6b1 and second layer 6b2, mounting terminal 21 is provided at each of four corners of the outer bottom face of first layer 6b1, and second layer 6b2 contacts flat layer 5. First layer 6b1 has a thickness smaller than that of second layer 6b2, for example.

In this crystal oscillator, notch portion 12 for providing probe contact terminal 8 is formed only on first layer 6b1. In other words, notch portion 12 is provided on first layer 6b1 at the position of the central region of each side of lower frame wall layer 6b. Each notch portion 12 is within a small rectangular region which is placed so as to contact a side of the outer bottom face of container main body 1 and is provided with no first layer 6b1, with upper frame wall layer 6a laminated on flat layer 5 at the position in which the region is formed. Notch portion 12 is surrounded in three directions by first layer 6b1 and opened in the other one direction to the side of the outer periphery of container main body 1.

The laminated surface of second layer 6b2 on first layer 6b1 is exposed at the position of notch portion 12, and probe contact terminal 8 is provided on the entire exposed surface. Of four probe contact terminals thus provided, for example, probe contact terminals 8 provided on a pair of long sides of the outer bottom face of container main body 1 are writing terminals 8b, and probe contact terminals 8 provided on short sides are crystal inspection terminals 8a.

In this configuration, notch portion 12 formed on first layer 6b1 is opened to the outer periphery of the outer bottom face of container main body 1, and therefore the probe can easily be abutted against probe contact terminal 8 formed on the bottom face of notch portion 12. Furthermore, by reducing the thickness of first layer 6b1, the probe is more easily abutted.

The surface mount type crystal oscillator according to a fifth exemplary embodiment shown in FIG. 8A comprises bonding mounting substrate 17 having a recess formed on the one main surface with IC chip 2 accommodated in the recess and crystal unit 16 hermetically encapsulating crystal blank 3. This crystal oscillator is made by bonding mounting substrate 17 to crystal unit 16 to integrate the former with the latter.

Crystal unit 16 uses a container main body comprising a laminated ceramic and having a recess on one main surface. Crystal blank 3 is an AT-cut quartz crystal blank similar to that shown in FIG. 2. Opposite sides of one end of crystal blank 3 are fixed on the inner bottom surface of the recess of container main body 1 by conductive adhesive 11, whereby crystal blank 3 is held horizontally in the recess. Metal ring 20 is provided on the peripheral edge of the opening of the recess, metal cover 4 is bonded to metal ring 20 by seam welding, and crystal blank 3 is hermetically encapsulated in the recess of container main body 1. At four corners of the outer bottom face of container main body 1 are provided connection terminals (not shown), respectively. Connection terminals include a pair of terminals electrically connected to crystal blank 3 and a terminal for grounding the metal cover.

Mounting substrate 17 comprises a laminated ceramic including substantially rectangular flat layer 5, and frame-shaped frame wall layer 6 laminated on one surface of flat layer 5 and having an opening. The opening of frame wall layer 6 defines a recess in which IC chip 2 is accommodated. At four corners of the upper surface of frame wall layer 6 are formed bonding terminals which are used for electrical connection to crystal unit 16, and by electrically and mechanically bonding the bonding terminal of mounting substrate 17 to the connection terminal of crystal unit 16 by solder 18 or the like, mounting substrate 17 is bonded to the bottom face of crystal unit 16. IC chip 2 is fixed on the inner bottom face of the recess of mounting substrate 17 by flip chip bonding. IC chip 2 is thus electrically connected to the bonding terminal through a conductive path (not shown) formed on mounting substrate 17.

As in the exemplary embodiments described above, mounting terminals which are used for surface-mounting the crystal oscillator on the wiring board are provided at four corners of the outer bottom face of mounting substrate 17, that is, the surface on which the recess is not formed. The mounting terminals are electrically connected to IC chip 2 through a conductive path (not shown) provided on the mounting substrate.

In this crystal oscillator, notch portion 12 is provided on flat layer 5 of mounting substrate 17 as in the crystal oscillator shown in the first exemplary embodiment. In other words, notch portion 12 is provided on the central region of each side of flat layer 5b, that is, at the position between mounting terminals. Notch portion 12 is surrounded in three directions by flat layer 5 and opened in the other one direction to the outer periphery of mounting substrate 17. In notch portion 12, the lower surface of frame wall layer 6 is exposed, and probe contact terminal 8 is formed on the entire exposed surface. Of four probe contact terminals thus provided, for example, probe contact terminals 8 provided on a pair of long sides of lower frame wall layer 6b are writing terminals 8b electrically connected to a temperature compensation mechanism in IC chip 2, and probe contact terminals 8 provided on short sides are crystal inspection terminals 8a electrically connected to crystal blank 3.

Alternatively, in this exemplary embodiment, flat layer 5 may be formed from first layer 5a and second layer 5b as an upper layer for first layer 5a as in the case shown in the second exemplary embodiment. FIG. 8B shows a crystal oscillator using mounting substrate 17 including flat layer 5 comprising first layer 5a and second layer 5b. In this case, notch portion 12 is formed only on first layer 5a, second layer 5b is exposed at notch portion 12, and probe contact terminal 8 is formed on the entire exposed surface of second layer 5b.

In this configuration of the fifth exemplary embodiment, notch portion 12 formed on flat layer 5 or first layer 5a is opened to the outer periphery of mounting substrate 17, and therefore the probe can easily be abutted against probe contact terminal 8 formed on the bottom face of notch portion 12 when a measurement tool is used. Particularly, when notch portion 12 is provided only on first layer 5a to expose second layer 5b as shown in FIG. 8B, the probe can more easily be abutted by reducing the thickness of first layer 5a.

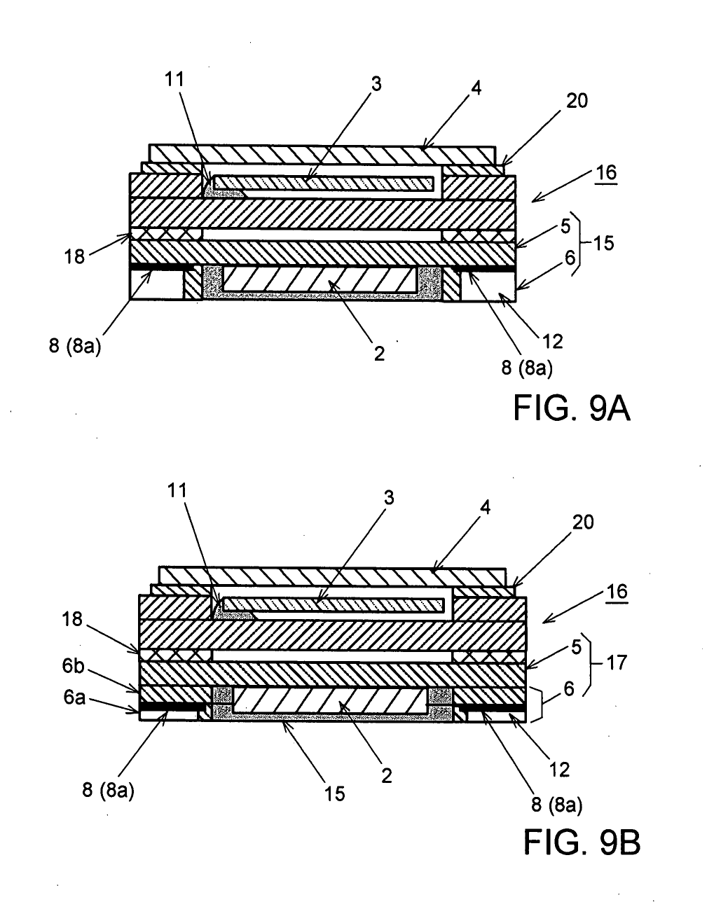

The surface mount type crystal oscillator according to a sixth exemplary embodiment shown in FIG. 9A is made by bonding to the bottom face of crystal unit 16 mounting substrate 17 comprising a recess and accommodating IC chip 2 therein as in the fifth exemplary embodiment shown in FIG. 8A, but it is different from the crystal oscillator of the fifth exemplary embodiment in the direction of the bonding of mounting substrate 17. In other words, provided that a recess for accommodating IC chip 2 is formed on one main surface of mounting substrate 17, the other main surface of mounting substrate 17 is bonded to the bottom face of crystal unit 16. In this case, bonding terminals are provided at four corners of the other main surface of mounting substrate 17, and accordingly, mounting terminals are provided at four corners of the surface of frame wall layer 6 surrounding the recess.

In this exemplary embodiment, notch portion 12 is provided on the central region of each side of frame wall layer 6, that is, at the position between mounting terminals. Each notch portion 12 is a small rectangular region which is provided on the outer periphery of frame wall layer 6 so as to contact the side of the outer bottom face of container main body 1, and is an only region where frame wall layer 6 is not formed. Therefore, notch portion 12 is surrounded in three directions by frame wall layer 6 and opened in the other one direction to the side of the outer periphery of mounting substrate 17. In notch portion 12, the lower surface of flat layer 5 is exposed, and probe contact terminal 8 is formed on the exposed surface. Of four probe contact terminals thus provided, for example, probe contact terminals 8 provided on a pair of long sides of frame wall layer 6 are writing terminals 8b electrically connected to a temperature compensation mechanism in IC chip 2, and probe contact terminals 8 provided on short sides are crystal inspection terminals 8a electrically connected to crystal blank 3.

Further, in this exemplary embodiment, frame wall layer 6 may have a configuration in which first layer 6a and second layer 6b are laminated as shown in FIG. 9B. Here, the mounting terminals are formed on the surface of first layer 6a, and second layer 6b contacts flat layer 5. In this configuration, notch portion 12 for providing probe contact terminal 8 is formed only on first layer 6a, and second layer 6b is exposed at the position of notch portion 12. Probe contact terminal 8 is provided on the entire exposed surface of second layer 6b in notch portion 12. Of four probe contact terminals thus provided, for example, probe contact terminals 8 provided on a pair of long sides of the outer bottom face of container main body 1 are writing terminals 8b, and probe contact terminals 8 provided on short sides are crystal inspection terminals 8a.

In this configuration of the sixth exemplary embodiment, notch portion 12 formed on frame wall layer 6 or first layer 6a is opened to the outer periphery of mounting substrate 17, the probe can easily be abutted against probe contact terminal 8 formed on the bottom face of notch portion 12 when a measurement tool is used. Particularly, when notch portion 12 is provided only on first layer 6a to expose second layer 6b as shown FIG. 9B, the probe can more easily be abutted by reducing the thickness of first layer 6a.

The first to sixth exemplary embodiments described above, crystal inspection terminal 8a and writing terminal 8b are provided as probe contact terminal 8. However, if the crystal oscillator is not of temperature compensation type, only crystal inspection terminal 8a may be provided as probe contact terminal 8 because writing terminal 8b is not needed. Furthermore, if a measurement of vibration characteristics with crystal blank 3 alone is not carried out, only writing terminal 8b may be provided as probe contact terminal 8 because crystal inspection terminal 8a is not needed. Furthermore, four terminals may be needed for writing temperature compensation data depending on the type of IC chip 2, and in this case, four writing terminals may be provided without providing the crystal inspection terminal. How the probe contact terminal is divided between the crystal inspection terminal and the writing terminal may be selected as required.

If the size of notch portion 12 permits, the probe contact terminal provided on notch portion 12 may be divided to form a plurality of probe contact terminals 8 on one notch portion 12. In this way, for example, four writing terminals 8b and two crystal inspection terminals 8a may be placed on one crystal oscillator.

In the explanations described above, probe contact terminal 8 is formed on the entire exposed surface of the upper layer by notch portion 12, but for facilitating division into individual container main bodies from a ceramic sheet having a size corresponding to a plurality of container main bodies, probe contact terminal 8 may be provided slightly away from the outer periphery of the container main body. Of course, provision of notch portion 12 results in a decrease in thickness of the laminate of ceramic sheets at the area, and therefore even if probe contact terminal 8 is provided on the entire exposed surface in notch portion 12, division from the laminate into individual container main bodies is not hindered.

It has been described that the shape of the region of notch portion 12 is a small rectangle, but it may be an arc-shaped region.

What is claimed is:

1. A surface mount type crystal oscillator comprising:
a crystal blank;
an IC chip including at least an oscillating circuit using the crystal blank;
a container main body provided with a recess on one main surface thereof, the IC chip and the crystal blank in the recess hermetically encapsulating in the recess; and
a probe contact terminal formed on an outer surface of the container main body and electrically connected to the IC chip and/or the crystal blank,
wherein the container main body comprises a laminated ceramic in which a flat layer and a frame wall layer which forms a side wall of the recess are laminated,
a mounting terminal electrically connected to the IC chip is provided on an outer bottom face of the flat layer,
a notch portion which is opened to outer periphery of the container main body is formed on the flat layer within a region where the frame wall layer is laminated on the flat layer, and
an upper layer just above the flat layer is exposed at the notch portion, and the probe contact terminal is provided on an exposed surface of the upper layer by the notch portion.

2. The crystal oscillator according to claim 1, wherein the upper layer is the frame wall layer.

3. The crystal oscillator according to claim 1, wherein the probe contact terminal is provided on the entire exposed surface of the upper layer.

4. The crystal oscillator according to claim 1, wherein the flat layer is made by laminating a first layer including the mounting terminal on an outer bottom face thereof and a second layer on which the IC chip is fixed, the upper layer is the second-layer, and the notch portion is provided on the first layer.

5. A surface mount type crystal oscillator comprising:
a crystal blank;
an IC chip including at least an oscillating circuit using the crystal blank;
a container main body provided with a first recess and a second recess on opposite main surfaces, respectively, the crystal blank hermetically encapsulated in the first recess and the IC chip accommodated in the second recess;
a probe contact terminal formed on the outer surface of the container main body and electrically connected to the IC chip and/or the crystal blank; and
a mounting terminal electrically connected to the IC chip,
wherein the container main body comprises a laminated ceramic including a flat layer, an upper frame wall layer laminated on a first main surface of the flat layer and forming a side wall of the first recess, and a lower frame wall layer laminated on a second main surface of the flat layer and forming a side wall of the second recess,
the mounting terminal is provided on an outer bottom face of the lower frame wall layer,
a notch portion which is opened to outer periphery of the container main body is formed on the lower frame wall layer, and
an upper layer just above the lower frame wall layer is exposed at the notch portion, and the probe contact terminal is provided on an exposed surface of the upper layer by the notch portion.

6. The crystal oscillator according to claim 5, wherein the upper layer is the flat layer.

7. The crystal oscillator according to claim 5, wherein the probe contact terminal is provided on the entire exposed surface of the upper layer.

8. The crystal oscillator according to claim 5, wherein the lower frame wall layer is made by laminating a first layer including the mounting terminal on an outer bottom face thereof and a second layer contacting the flat layer, the upper layer is the second layer, and the notch portion is provided on the first layer.

9. A surface mount type crystal oscillator comprising:
a crystal unit having a crystal blank hermetically encapsulated in a container main body;
an IC chip including at least an oscillating circuit using the crystal unit;
a mounting substrate including a recess on one main surface thereof, with the IC chip accommodated in the recess; and
a probe contact terminal formed on an outer surface of the mounting substrate and electrically connected to the IC chip and/or the crystal blank,
wherein the mounting substrate comprises a laminated ceramic in which a flat layer and a frame wall layer is laminated, the flame wall layer forming a side wall of the recess and being bonded to the crystal unit,
a mounting terminal electrically connected to the IC chip is provided on an outer bottom face of the flat layer,
a notch portion which is opened to outer periphery of the mounting substrate is formed on the flat layer within a region where the frame wall layer is laminated on the flat layer, and
an upper layer just above the flat layer is exposed at the notch portion, and the probe contact terminal is provided on an exposed surface of the upper layer by the notch portion.

10. The crystal oscillator according to claim 9, wherein the upper layer is the frame wall layer.

11. The crystal oscillator according to claim 9, wherein the probe contact terminal is provided on the entire exposed surface of the upper layer.

12. The crystal oscillator according to claim 9, wherein the flat layer is made by laminating a first layer including the mounting terminal on an outer bottom face thereof and a second layer on which the IC chip is fixed, the upper layer is the second layer, and the notch portion is provided on the first layer.

13. A surface mount type crystal oscillator comprising:
a crystal unit having a crystal blank hermetically encapsulated in a container main body;
an IC chip including at least an oscillating circuit using the crystal unit;
a mounting substrate including a recess on one main surface thereof, with the IC chip accommodated in the recess; and
a probe contact terminal formed on an outer surface of the mounting substrate and electrically connected to the IC chip and/or the crystal blank,
wherein the mounting substrate comprises a laminated ceramic made by laminating a flat layer bonded to the crystal unit and a frame wall layer forming a side wall of the recess,
a mounting terminal electrically connected to the IC chip is provided on an outer bottom face of the frame wall layer,
a notch portion which is opened to outer periphery of the mounting substrate is formed on the frame wall layer, and
an upper layer just above the frame wall layer is exposed at the notch portion, and the probe contact terminal is provided on an exposed surface of the upper layer by the notch portion.

14. The crystal oscillator according to claim 13, wherein the upper layer is the flat layer.

15. The crystal oscillator according to claim 13, wherein the probe contact terminal is provided on the entire exposed surface of the upper layer.

16. The crystal oscillator according to claim 13, wherein the frame wall layer is made by laminating a first layer including the mounting terminal on an outer bottom face thereof and a second layer contacting the flat layer, the upper layer is the second layer, and the notch portion is provided on the first layer.

17. The crystal oscillator according to claim 1, wherein the probe contact terminal is a crystal inspection terminal which is used for inspecting vibration characteristics of the crystal blank.

18. The crystal oscillator according to claim 1, wherein the probe contact terminal is a writing terminal which is used for writing temperature compensation data in the IC chip.
